(19) United States
(12) Patent Application Publication
(10) Pub. No.: US 2026/0123470 A1
(43) Pub. Date: Apr. 30, 2026

(54) BACK SIDE WAFER-SCALE POWER DELIVERY WITH AN ANISOTROPIC CONDUCTIVE FILM

(71) Applicant: Volantis Semiconductor, Inc., Portland, OR (US)

(72) Inventors: Tapabrata Ghosh, San Francisco, CA (US); Kevin Nan Lam, Pleasanton, CA (US)

(73) Assignee: Volantis Semiconductor, Inc., Portland, OR (US)

(21) Appl. No.: 19/387,789

(22) Filed: Nov. 13, 2025

Related U.S. Application Data
(63) Continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H01L 23/538; H01L 21/48; H01L 23/00; H01L 23/498; H01L 25/065

(52) U.S. Cl. CPC H10W 70/611; H10W 70/092; H10W 70/098; H10W 70/635; H10W 70/66; H10W 90/00; H10W 90/724

(57) ABSTRACT

Power delivery is enabled for wafer-scale integration. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs) is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

### RELATED APPLICATIONS

This application claims the benefit of U.S. provisional applications “Back Side Wafer-Scale Power Delivery With An Anisotropic Film” Ser. No. 63/720,216, filed Nov. 14, 2024, “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

This application is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025 is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Film” Ser. No. 63/720,216, filed Nov. 14, 2024.

The U.S. patent application “Back Side Power Delivery For Wafer-Scale Integration Sith Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to power delivery and more particularly to back side wafer-scale power delivery with an anisotropic conductive film.

### BACKGROUND

Physical characteristics play an enormously important role in everyday life around the world. Shapes, colors, textures, and so on give distinct and often recognizable differentiation between various objects in our world. These physical characteristics can be attributed to the actual arrangement and structure of the very atoms that compose a given material and the object into which it is formed. Some of the characteristics are readily apparent by simply looking at or holding an object. A diamond, for example, looks and feels much different from a piece of talc. A diamond is one of the hardest substances found in nature. It is classified as a ten on the Mohs scale, which measures the relative hardness of different minerals. Talc, on the other hand, is one of the softest naturally occurring minerals. It is classified as a one on the Mohs scale. The respective physical characteristics of diamonds and talc are a direct result of the structure and makeup of the atoms that form them.

Historically, one of the earliest scientific phenomena observed was that matter tends to expand in size when its temperature increases. This expansion occurs in every state of matter-solid, liquid, and gas. This is easily perceived in everyday life, as snow melts or steam rises from a boiling pot. Expansion of matter due to rising temperature is a direct consequence of the behavior of atoms and molecules at the microscopic level. The origin of the kinetic theory of matter is as old as 50 BC when Lucretius proposed the idea that matter was made up of atoms bouncing off each other. Connecting this idea to the effects of temperature developed further with Francis Bacon in the early 1600s. Other scientists followed up on this idea, leading to Daniel Bernoulli publishing his paper on hydrodynamics in 1738, laying down the basis for the kinetic theory of gases. The theory states that matter is indeed composed of tiny particles—atoms and molecules—that are in constant motion. As the temperature of a substance rises, the average kinetic energy of these particles increases. The increased energy translates into more vigorous vibrations and movements, causing the particles to spread out and occupy more space. Understanding this basic reality of the physical world is essential to our control and management of life here on earth.

Computer systems are integral to societies in our world today. Computer systems are critical components used in banking, commerce, farming, trade, manufacturing, and so on, to name just a few. Computer systems themselves are made up of various components, such as processor components, memory components, input/output (I/O) components, communication components, etc. Every single physical computer component is governed by the physical characteristics of its constituent component parts. Further, each of the components must be packaged in a way suitable for forming the computer system. Of course, because computer systems are based on moving electric charge around, and because moving electric charge around takes energy, computer systems necessarily need to dissipate heat. The heat is a result of the non-ideal electrical characteristics that dominate life, which is the way the real world operates. Packaging computer system components in such a way as to maximize performance and simultaneously allow for efficient heat dissipation is a modern challenge that will need to be addressed for the foreseeable future.

### SUMMARY

As computer performance demands continue to rise, engineers have responded, in part, by placing more transistors on a chip. Whether designing processors, multi-core processors, system-on-chips (SoCs), etc. the trend has been clear-more transistors deliver better performance. As a result, today's SoCs can include tens of billions of transistors. One performance approach that has shown promise is wafer-scale integration (WSI). WSI can take different forms, such as interconnecting multiple die fabricated on the same wafer. Another WSI approach that has shown promise is to use a wafer as an interposer for other chips that are flip-chip mounted to the wafer. The wafer can then be used for routing between chips, for power delivery, for input/output (I/O) configurations, and so on. Thus, a single wafer may include many processor chips, SoCs, artificial intelligence (AI) accelerator chips, memory chips, and so on. However, power must be delivered to each transistor within each chip, which can present a significant challenge.

Disclosed techniques enable power delivery for wafer-scale integration. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs) is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

A method for power delivery is disclosed comprising: accessing a wafer-scale silicon interposer (WSSI), wherein a front side of the WSSI is bonded to a plurality of functional chips, wherein the WSSI includes a plurality of through-silicon vias (TSVs), and wherein the WSSI is associated with a first coefficient of thermal expansion (CTE); coupling, by an anisotropic conductive film (ACF), to a back side of the WSSI, a plurality of modular power substrates (MPSs), wherein each MPS is further coupled, based on the plurality of TSVs, to one or more functional chips within the plurality of functional chips; connecting mechanically the plurality of MPSs, to a unified control board (UCB), wherein the UCB includes a plurality of DC-to-DC power converters, and wherein the UCB is associated with a second coefficient of thermal expansion; and sending DC power, by the UCB, to the plurality of functional chips, wherein the sending includes one or more voltage conversions, wherein the sending is based on the plurality of MPSs.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for back side wafer-scale power delivery with an anisotropic conductive film.

FIG. 2 is a flow diagram for anisotropic conductive film path forming.

FIG. 3 is an illustration of an anisotropic conductive film.

FIG. 4 is a cross section of an apparatus for back side wafer-scale power delivery with an anisotropic conductive film.

FIG. 5 is a system diagram for back side wafer-scale power delivery with an anisotropic conductive film.

FIG. 6 is a cross section of an apparatus for back side power delivery for wafer-scale integration with an isometric grid compression plate.

### DETAILED DESCRIPTION

Techniques for back side wafer-scale power delivery with an anisotropic conductive film are disclosed. The rising popularity of AI applications has fueled a new race for processor performance. In the past, engineers focused on benchmarks that measured performance of a single processor such as integer, floating point, memory bandwidth, etc. Today, a wide variety of benchmarks, such as multicore, multithreaded, graphics, video editing, vector, cloud, and so on, are available to test performance. While these measurements remain important, performance measurements have shifted to include elements of AI acceleration including matrix multiply, dot product, matrix transpose functions, and so on. To achieve higher and higher levels of performance, these functions have driven hardware designers to integrate “matrix” units into current chip implementations and/or to create AI accelerators with necessary memory bandwidth and latency at a system level that can effectively accelerate AI operations driven by training and inferencing AI models.

Multiple techniques have been attempted to increase AI performance. One such approach is wafer-scale integration (WSI). WSI can use an entire wafer to build a system, accelerator, AI accelerator, etc. with many functional chips. Many possibilities exist to use WSI. In one example of a WSI implementation, the entire wafer is used as an interposer. This can be called a wafer-scale silicon interposer (WSSI). In this approach, multiple functional chips can be flip-chip bonded to the top of the interposer with controlled collapse chip connections (C4s). Thus, all interconnections to a circuit or chip, including data connections, control and signal connections, and so on, can be made at the top layer of the mounted chip. The connections at the top of the chip replace the traditional placement of pads at the periphery of the chip. Communications between the functional chips can be accomplished by metal layers within the silicon interposer, improving latency, signal integrity, parasitics, and/or bandwidth as many more wires can be established within the silicon wafer than would have been possible with a typical packaging interface. Thus, the WSSI can enable extremely high bandwidth buses and control signals between chips mounted to the WSSI. When multiple AI accelerators and memory chips are coupled with a wafer interposer, a significant acceleration in AI tasks can be achieved. While wafer-scale integration techniques, such as using a WSSI, can increase AI performance, power delivery can be a key challenge. The wafer interposer can have a different coefficient of thermal expansion than a typical board which can deliver power to the mounted chips. Thus, when operating, the wafer and the power board can move differently due to thermal expansion. This can cause cracked solder joints, broken connections, unreliable coupling, and so on.

To address these thermal challenges, power delivery technology is disclosed. A wafer-scale silicon interposer (WSSI) is accessed. A front side of the WSSI is bonded to a plurality of functional chips. The WSSI includes a plurality of through-silicon vias (TSVs) and is associated with a first coefficient of thermal expansion (CTE). An anisotropic conductive film (ACF) couples a back side of the WSSI to a plurality of modular power substrates (MPSs). In embodiments, the coupling enables an electrical connection without a solder reflow process. In other embodiments, the ACF comprises a plurality of conductive particles. The plurality of conductive particles can form a plurality of conductive paths in a single direction within the ACF. Each MPS is further coupled to one or more functional chips by the plurality of TSVs. The MPSs are connected mechanically to a unified control board (UCB) which is associated with a second coefficient of thermal expansion. In embodiments, the first coefficient of thermal expansion is different than the second coefficient of thermal expansion. The UCB includes a plurality of DC-to-DC power converters. DC power is sent to the functional chips by the UCB. The sending includes one or more voltage conversions. The sending is based on the plurality of MPSs.

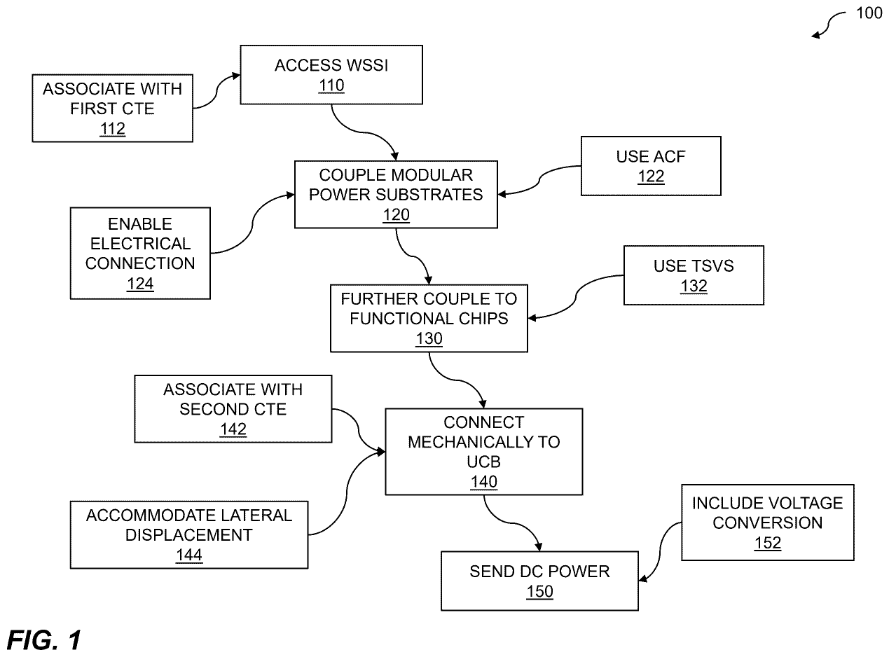

FIG. 1 is a flow diagram for back side wafer-scale power delivery with an anisotropic conductive film. The flow 100 includes accessing a wafer-scale integration interposer (WSSI) 110. The wafer can be a 300 mm wafer, a 200 mm wafer, or a wafer of another size. The wafer can comprise silicon or another suitable material. A front side of the WSSI is bonded to a plurality of functional chips. The functional chips can include general purpose chips such as processor chips, multiprocessor chips, application-specific integrated circuits (ASICs), memory chips, and so on. The functional chips can further include specialty processing chips such as accelerators for artificial intelligence training and inferences. The WSSI includes a plurality of through-silicon vias (TSVs). A TSV can include an electrical connection that completely passes through a wafer such as a silicon wafer or a die. The plurality of TSVs can be oriented vertically in order to enable connections between the front side of the wafer and the back side of the wafer. Chips such as the functional chips can be positioned such that connections to the chips align with the TSVs. The WSSI is associated with a first coefficient of thermal expansion (CTE) 112. The CTE can be a material property. The CTE can determine how far the WSSI will expand when a specific amount of heat is applied. The heat can be generated by the functional chips, DC-to-DC converters, and/or other elements. As more heat is applied, the WSSI can continue to expand according to the first CTE. Likewise, as heat is removed, the WSSI can contract according to the first CTE.

The flow 100 includes coupling, by an anisotropic conductive film (ACF), to a back side of the WSSI, a plurality of modular power substrates (MPSs) 120. Modular power substrates can include one or more electrical elements, connectors, and so on. The electrical elements can include DC-to-DC converters. Any number of voltage conversions can be included so that the functional chips receive power at an appropriate voltage for functionality. The connectors can include a high-power connector and a plurality of rigid-flex strips. The substrate associated with an MPS to which the electrical elements, connectors, and so on are mounted can include a variety of materials comprising organic or inorganic substrates.

The coupling can use an ACF 122, which can be used to form electrical connections. The ACF can comprise a film or a paste. ACFs can provide a solderless connection between chips, boards, and so on. Thus, the use of an ACF can bond elements with an electrical connection while avoiding a solder reflow process common with soldering parts to a printed circuit board. The ACF material can include dispersed conductive particles within the body of the ACF. The ACF can be applied between two contacts. In some use cases, the conductive particles can be pre-aligned with the contacts. In embodiments, the ACF comprises a plurality of conductive particles, wherein the plurality of conductive particles forms a plurality of conductive paths in a single direction within the ACF.

In some embodiments, the plurality of conductive paths is based on thermocompression. Pressure and heat can be applied to the ACF which can align the particles to produce electrical “wires” (e.g., electrical connections) vertically within the film, providing a connection between the contacts. The heat needed to form the connections can be less than the temperature necessary for a solder reflow oven. This can avoid problems associated with higher heat levels such as warping the WSSI or cracking C4 and/or micro-bump connections between the functional chips and the WSSI. In embodiments, the coupling enables an electrical connection 124 without a solder reflow process. The ACF can also include non-conducting materials which can prevent electrical connections horizontally within the ACF between the vertical wires which are formed (e.g., can prevent internal “shorting”). The vertical electrical connections can be created with an electric field, a magnetic field, a combination, or other methods that require no pressure or increase in temperature. In other embodiments, the plurality of conductive paths is based on an electric field. In embodiments, the plurality of conductive paths is based on a magnetic field.

In the flow 100, each MPS is further coupled 130 to one or more functional chips within the plurality of functional chips. The coupling can be based on the plurality of TSVs 132. In embodiments, the plurality of MPSs is based on a form factor mirroring one or more corresponding functional chips, within the plurality of functional chips, on the front side of the WSSI. The form factor can include a square form factor, a rectangular form factor, and so on. The TSVs can be designed to transfer power from the MPSs to the functional chips.

The flow 100 includes connecting mechanically the plurality of MPSs to a unified control board (UCB) 140. The UCB includes a plurality of DC-to-DC power converters. The DC-to-DC converters can convert DC power from a high voltage range to a low voltage range (e.g., buck conversion). In a usage example, the DC-to-DC converters can convert DC power from a high voltage range, such as 48 volts to 54 volts, to a lower voltage range, such as 12 volts to 13.5 volts. The higher voltage range can be a voltage range normally supplied to racks within a data center. The UCB can include one or more digital controller chips to control the DC-to-DC power converters. The digital control circuits can comprise a processor, a multiprocessor, a microcontroller, and so on. The UCB is associated with a second coefficient of thermal expansion (CTE) 142. In embodiments, the first coefficient of thermal expansion is different than the second coefficient of thermal expansion.

The connecting mechanically can be accomplished using plug-and-socket connectors, terminals, cables, and so on. The connecting mechanically of each MPS to the UCB can be accomplished using a DC power connector and a plurality of rigid-flex strips. The connecting mechanically can be based on a high voltage socket. The DC power connector can be the high voltage socket. In embodiments, the connecting mechanically is based on a plurality of high voltage sockets, wherein the connecting mechanically accommodates a lateral displacement 144 between the WSSI and the UCB due to thermal expansion during operation. The modularity of the MPSs can provide a flexible power delivery system to the functional chips, which can accommodate different movements of the WSSI and UCB due to different coefficients of thermal expansion. For example, an MPS at one side of the WSSI can be decoupled from an MPS on the other side of the WSSI, thus accommodating various movements across the WSSI and/or UCB. In addition, the high-power socket can provide flexibility to accommodate lateral movement between the UCB and the MPS (which is attached to the WSSI). In embodiments, each MPS in the plurality of MPSs includes one or more rigid-flex strips, wherein the one or more rigid-flex strips enable power control, of each corresponding MPS, by a digital controller chip coupled to the UCB. The rigid-flex strips can further accommodate lateral movement between the UCB and MPS due to thermal expansion. These factors can allow the MPSs to provide “flex” between the UCB and the WSSI as they expand at different rates.

The flow 100 includes sending DC power 150. The DC power is sent by the UCB to the plurality of functional chips. The sending includes one or more voltage conversions 152. Any number of voltage conversions can be included so that the functional chips receive power at an appropriate voltage for operation. In embodiments, a first voltage conversion is accomplished by the plurality of DC-to-DC power converters included on the UCB. In some embodiments, the sending includes a second voltage conversion, wherein the second voltage conversion is accomplished by the plurality of MPSs.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

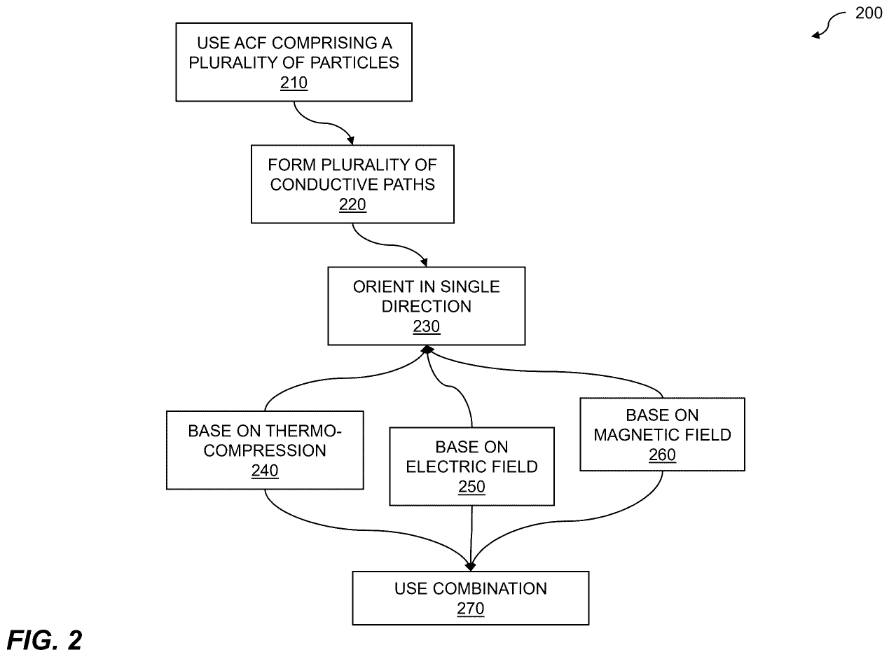

FIG. 2 is a flow diagram for anisotropic conductive film path forming. Anisotropic conductive film path forming can enable back side wafer-scale power delivery with an anisotropic conductive film. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs) is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

The flow 200 includes using an anisotropic conductive film (ACF) comprising a plurality of particles 210. The plurality of particles withing the ACF can be used to form electrical connections. The ACF can comprise a film or a paste. ACFs can provide a solderless connection between chips, boards, and so on. Thus, the use of an ACF can bond elements with an electrical connection while avoiding a solder reflow process common with soldering parts to a printed circuit board. The ACF material can include dispersed conductive particles within the body of the ACF. The ACF can be applied between two contacts. In some use cases, the conductive particles can be pre-aligned with the contacts. In embodiments, the ACF comprises a plurality of conductive particles, wherein the plurality of conductive particles forms a plurality of conductive paths in a single direction within the ACF.

The flow 200 includes forming a plurality of conductive paths 220 in the ACF. The conductive paths enable current conduction between the two film surfaces, i.e., between the film's top surface and the film's bottom surface. In this manner, an electrical connection can be formed between a top surface component and a bottom surface component through the ACF, which allows for the mechanical properties of the ACF to be imputed to the electrical path formed by the conductive particles. Thus, the elasticity inherent in an ACF can provide electrical conductivity in spite of thermally-induced coefficients of expansion mismatches. The flow 200 includes forming the conductive paths oriented in a single direction 230. Specifically, the anisotropicity of the conductive film enables electrical conduction through the narrow, top-to-bottom dimension of the film, while enabling electrical insulation across the wide, spanning horizontal dimension of the film. The “columns” of electrically conducting particles in the “North-South” direction do not appreciably conduct in the “East-West” direction between or among columns.

The flow 200 includes basing the orientation in a single direction on thermocompression 240. Pressure and heat can be applied to the ACF which can align the particles to produce electrical “wires” (e.g., electrical connections) vertically within the film, providing a connection between the contacts. The heat needed to form the connections can be less than the temperature necessary for a solder reflow oven. This can avoid problems associated with higher heat levels such as warping the WSSI or cracking C4 and/or micro-bump connections between the functional chips and the WSSI. The ACF can also include non-conducting materials which can prevent electrical connections horizontally within the ACF between the vertical wires which are formed (e.g., can prevent internal “shorting”). The flow 200 includes basing the orientation in a single direction on an electric field 250. The electric field can be applied between top and bottom contacts on the ACF. The electric field can cause the conductive particles to align along the electric field lines to provide a permanent or semipermanent connection between corresponding upper and lower contacts. For some applications, the orientation in a single direction can be based on a magnetic field 260. A magnetic field can be used when the particles and/or the ACF itself have magnetoresponsive properties. For some applications, a combination of the thermocompression, electrical, and magnetic techniques are used 270. Thus, the vertical electrical connections can be created with a thermocompression application, an electric field, a magnetic field, or a combination of any two of the three described methods. In embodiments, the plurality of conductive paths is based on an electric field. In embodiments, the plurality of conductive paths is based on a magnetic field. In embodiments, the plurality of conductive paths is based on a combination of electrical fields and/or magnetic fields and/or thermocompression techniques.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

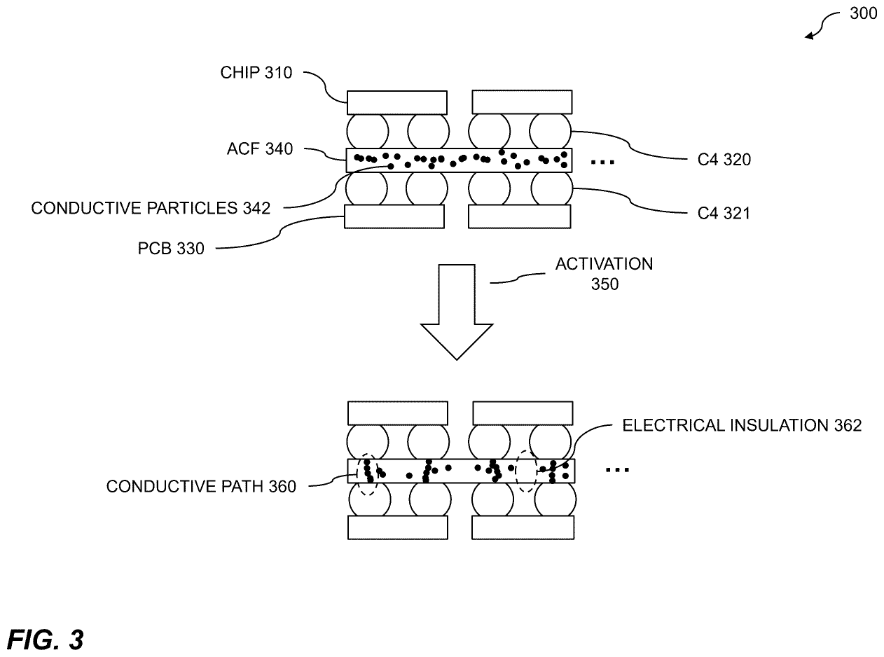

FIG. 3 is an illustration of an anisotropic conductive film (ACF). An anisotropic conductive film can enable back side wafer-scale power delivery. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs), is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

The illustration 300 includes a chip 310. The chip can be an integrated circuit (IC). The IC can be a processor, memory, system-on-chip (SoC), AI accelerator, and so on. The chip can include a plurality of controlled collapse chip connections (C4s), such as C4 320 and C4 321. The C4s can be bonded to the chip such that it can be flip-chip mounted to other elements such as a board, wafer interposer, and so on. The C4s can comprise electrical contacts which can be used to connect to other components via an anisotropic conductive film (described below). While C4s are shown, any type of contact can be bonded to the chip including micro-bumps, pads, and so on.

The illustration 300 includes a printed circuit board (PCB) 330. The PCB can comprise a unified control board (UCB) such as described above. The PCB can also include a plurality of controlled collapse chip connections (C4s). The C4s can comprise electrical contacts which can be used to connect to other components, such as chip 310, via an anisotropic conductive film. While C4s are shown, any type of contact can be bonded to the chip including micro-bumps, pads, and so on.

The illustration 300 includes an anisotropic conductive film (ACF) 340. An anisotropic conductive film can be used as an adhesive interconnect and can provide a solderless connection between components such as integrated circuits (ICs), circuit boards, display panels, and so on. Thus, the use of an ACF can establish an electrical connection while avoiding a solder reflow process common with soldering parts to a printed circuit board. The ACF can comprise a file or a paste. ACFs can comprise an adhesive material which includes dispersed conductive particles 342 within the adhesive. In embodiments, the ACF comprises a plurality of conductive particles, wherein the plurality of conductive particles forms a plurality of conductive paths in a single direction within the ACF. The single direction can be vertical as shown in illustration 300, from the chip 310 to the PCB 330 and vice-versa. An ACF can be applied between two contacts, such as the C4s as shown in illustration 300. Electrical connections between the contacts can be established between the chip and the PCB, through the ACF, when the ACF is activated. The activation 350 can include application of thermocompression, an electric field, a magnetic field, and so on. The ACF can form multiple connections between ICs, boards, and so on. The connections can be conductive paths 360 through the ACF formed by the conductive particles. Thus, in some embodiments, the plurality of conductive paths is based on thermocompression. In other embodiments, the plurality of conductive paths is based on an electric field. In other embodiments, the plurality of conductive paths is based on a magnetic field. Each conductive path can be electrically insulated 362 from other paths.

A plurality of conductive connecting materials can be used to couple one or more chips to a substrate, PCB, interposer, etc. In embodiments, the plurality of conductive connecting materials comprises a plurality of elastomer sheets. The plurality of elastomer sheets can include a variety of materials, configurations, and so on. In some embodiments, a single elastomer sheet can be used. An elastomer sheet can comprise conductive particles, which can be a filament, such as brass, gold, etc., embedded in a sheet of silicone rubber or another suitable material. The conductive particles are shown to be distributed throughout the conductive sheet in a “unprogrammed” state, as in ACF 340. That is, as shown, the conductive paths have yet to be “activated”. However, the conductive elements, or filaments, can be “pre-programmed” to be embedded on a pitch. The pitch can be designed to match a connector array, such as a ball grid array (BGA) of the MPS. Thus, the elastomer sheet may not need any activation in order to form one or more conductive paths. The elastomer sheet can be held in place with a compression force. An adhesive backing can be added to the elastomer sheet. Thus, the elastomer sheet can accomplish adhesion of the one or more chips to the one or more PCBs. The elastomer sheet can provide conduction paths between the one or more chips and the one or more PCBs.

In embodiments, the plurality of conductive connecting materials comprises a plurality of anisotropic conductive films (ACFs). An ACF can include a film which is both conductive and adhesive. The ACF can be activated using heat, pressure, etc. In embodiments, each ACF in the plurality of ACFs comprises a plurality of conductive particles, wherein the plurality of conductive particles forms a plurality of conductive paths in a single plane within each ACF in the plurality of ACFs. The ACF can be activated using heat, pressure, one or more electrical fields, etc. The activation can include two or more of the aforementioned techniques. When activated by an amount of heat, the ACF can become slightly tacky. The amount of heat can be low enough to prevent reflow of soldered connections, further diffusion of materials, and so on. The heating of the ACF can cause conductive particles in the ACF to be trapped by prominences such as contacts. When a pressure technique is used, the amount of pressure applied enables the attaching of, for example, the MPSs. The conducting paths through the ACF can be enabled by electrical “programming” to determine conducting paths through the ACF after application of the ACF. The ACF can be “pre-programmed” (thus, in that case, no activation is required to form one or more conductive paths). The conducting paths can be predetermined by setting the conducting paths through the ACF prior to application of the ACF. The ACF is then placed so that conducting paths through the ACF align with the electrical contacts above and below the ACF, e.g., C4 320 and C4 321.

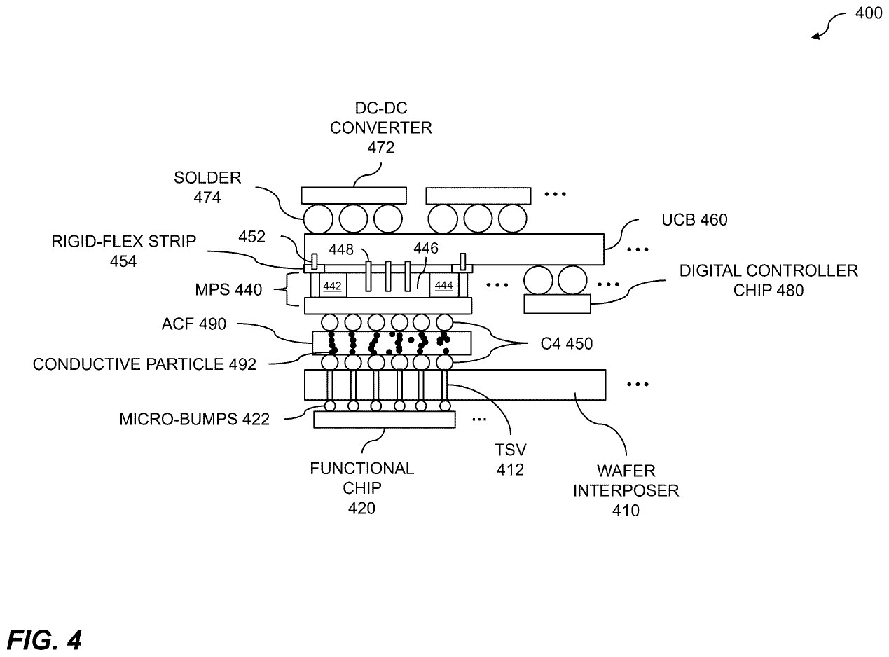

FIG. 4 is a cross section of an apparatus for back side wafer-scale power delivery with an anisotropic conductive film. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs) is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

Wafer-scale integration (WSI) can be achieved through the use of a wafer-scale silicon interposer. The cross section 400 discloses an apparatus for power delivery comprising: a wafer-scale silicon interposer (WSSI), wherein a front side of the WSSI is bonded to a plurality of functional chips, wherein the WSSI includes a plurality of through-silicon vias (TSVs), and wherein the WSSI is associated with a first coefficient of thermal expansion; a plurality of modular power substrates (MPSs), wherein the plurality of MPSs is coupled to a back side of the WSSI; a unified control board (UCB), wherein the UCB is connected mechanically to the plurality of MPSs, wherein the UCB includes a plurality of DC-to-DC power converters, and wherein the UCB is associated with a second coefficient of thermal expansion; and an anisotropic conductive film (ACF), wherein the ACF couples the plurality of MPSs to a back side of the WSSI, wherein the ACF enables each MPS to be further coupled, based on the plurality of TSVs, to one or more functional chips within the plurality of functional chips.

The cross section 400 includes a wafer-scale silicon interposer (WSSI) 410. The wafer interposer can include organic materials or inorganic materials. The WSSI can comprise a 300 mm wafer, a 200 mm wafer, or some other size wafer. A front side of the WSSI is bonded to a plurality of functional chips 420. The functional chips can include a processor chip, multi-core processor chip, system-on-a-chip, memory chip, application-specific integrated circuit (ASIC), artificial intelligence accelerator, and so on. The bonding can include flip-chip mounting the chips to the wafer interposer. Various techniques can be used to make connections to the top of a functional chip. In a usage example, a technique based on micro-bumps 422 can be used. The WSSI includes a plurality of through-silicon vias (TSVs) 412. A back side of the WSSI can include a plurality of C4s 450. The C4s can be used to couple the WSSI to other elements. The TSVs can provide a connection between the micro-bumps and the C4s. These connections can be used to deliver power to the functional chips through the back side of the WSSI. The WSSI is associated with a first coefficient of thermal expansion.

The cross section 400 includes a plurality of modular power substrates (MPSs) 440. The plurality of MPSs is coupled to a back side of the WSSI. Connections between the wafer interposer and the MPSs can be accomplished using the C4s described above. The MPSs can include a plurality of step-down power modules and/or DC-to-DC converters such as those shown at 442 and 444. The DC-to-DC converters on the MPSs can accomplish altering of a DC voltage. The MPSs can provide a second voltage conversion. The second voltage conversion can include a second DC-to-DC voltage conversion. The second voltage conversion can result in a voltage which is appropriate for the functionality of the functional chips. The MPS can also provide a voltage for the functional chips appropriate for I/O circuits which can be different than the voltage required for functional circuits.

The cross section 400 includes a unified control board (UCB) 460. The UCB is connected mechanically to the plurality of MPSs. The connection can be based on a connector 446. The connector can be used to mechanically connect the MPSs to the UCB. The connector can include a socket on the UCB. The mechanical connection can include one or more pins 448 which can be inserted into the socket. The mechanical connection can accommodate a maximum lateral displacement of the UCB due to thermal expansion during operation. The lateral displacement can result from various amounts of thermal expansion of the WSSI, the UCB, and/or the MPS during operation. Each component can have a different CTE and thus can expand at different rates. In addition to the power connector, the MPS can include a rigid-flex strip 454. The rigid-flex strip can provide a mechanical connection between the MPS and a UCB. The plurality of rigid-flex strips can provide control signals, data, and so on. The mechanical connection can include a plurality of rigid-flex strips. The plurality of rigid-flex strips can include one or more power control signals from the digital controller chip to the plurality of MPSs. The plurality of rigid-flex strips can include one or more signals such as one or more power control signals. The rigid-flex strips can include a socket into which one or more plugs, pins, etc., such as 452, can be inserted to couple the rigid-flex strip to the UCB. The UCB includes a plurality of DC-to-DC power converters 472. The DC-to-DC power converters can convert a first DC voltage to a second DC voltage. The DC-to-DC power converters can be coupled to the UCB with solder bumps (474). The DC-to-DC converters can be controlled by a digital controller chip 480. The UCB is associated with a second coefficient of thermal expansion. In embodiments, the first coefficient of thermal expansion is different than the second coefficient of thermal expansion.

The cross section 400 includes an anisotropic conductive film (ACF) 490. As described earlier, an ACF can be used as an adhesive interconnect and can provide a solderless connection between components such as integrated circuits (ICs), circuit boards, display panels, and so on. Thus, the use of an ACF can establish an electrical connection while avoiding a solder reflow process common with soldering parts to a printed circuit board. The ACF can comprise a file or a paste. ACFs can comprise an adhesive material which includes dispersed conductive particles 492 within the adhesive. In embodiments, the ACF comprises a plurality of conductive particles, wherein the plurality of conductive particles forms a plurality of conductive paths in a single direction within the ACF. The ACF couples the plurality of MPSs to a back side of the WSSI. The ACF enables each MPS to be further coupled, based on the plurality of TSVs, to one or more functional chips within the plurality of functional chips.

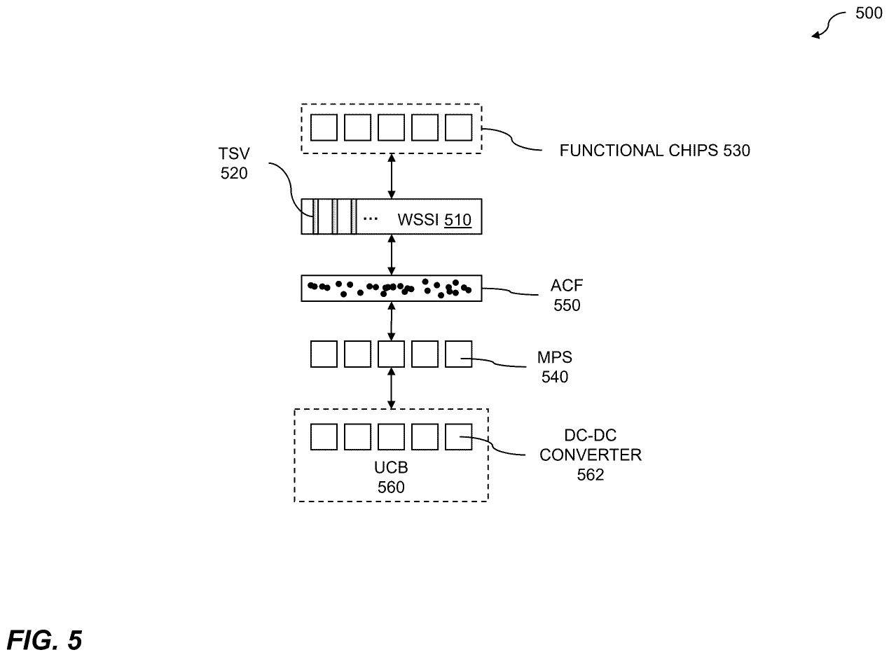

FIG. 5 is a system diagram for back side wafer-scale power delivery with an anisotropic conductive film. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs) is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

The system 500 can include a system for power delivery comprising: a wafer-scale silicon interposer (WSSI), wherein a front side of the WSSI is bonded to a plurality of functional chips, wherein the WSSI includes a plurality of through-silicon vias (TSVs), and wherein the WSSI is associated with a first coefficient of thermal expansion; a plurality of modular power substrates (MPSs), wherein the plurality of MPSs are coupled to a back side of the WSSI; a unified control board (UCB), wherein the UCB is connected mechanically to the plurality of MPSs, wherein the UCB includes a plurality of DC-to-DC power converters, and wherein the UCB is associated with a second coefficient of thermal expansion; and an anisotropic conductive film (ACF), wherein the ACF couples the plurality of MPSs to a back side of the WSSI, and wherein the ACF enables each MPS to be further coupled, based on the plurality of TSVs, to one or more functional chips within the plurality of functional chips, wherein the system, when provided DC power, is configured to: send DC power, by the UCB, to the plurality of functional chips, wherein the sending includes one or more voltage conversions, wherein the sending is based on the plurality of MPSs.

The system 500 includes a wafer-scale silicon interposer (WSSI) 510. A front side of the WSSI is bonded to a plurality of functional chips 530. The WSSI includes a plurality of through-silicon vias (TSVs) 520. The WSSI is associated with a first coefficient of thermal expansion. The system 500 includes a plurality of modular power substrates (MPSs) 540. The plurality of MPSs is coupled to a back side of the WSSI. The system 500 includes a unified control board (UCB) 560. The UCB is connected mechanically to the plurality of MPSs. The UCB includes a plurality of DC-to-DC power converters 562. The UCB is associated with a second coefficient of thermal expansion. In embodiments, the first coefficient of thermal expansion is different than the second coefficient of thermal expansion. The system 500 includes an anisotropic conductive film (ACF) 550. The ACF couples the plurality of MPSs to a back side of the WSSI. The ACF enables each MPS to be further coupled, based on the plurality of TSVs, to one or more functional chips within the plurality of functional chips. The system 500 is configured to send DC power, by the UCB, to the plurality of functional chips. The sending includes one or more voltage conversions. The sending is based on the plurality of MPSs.

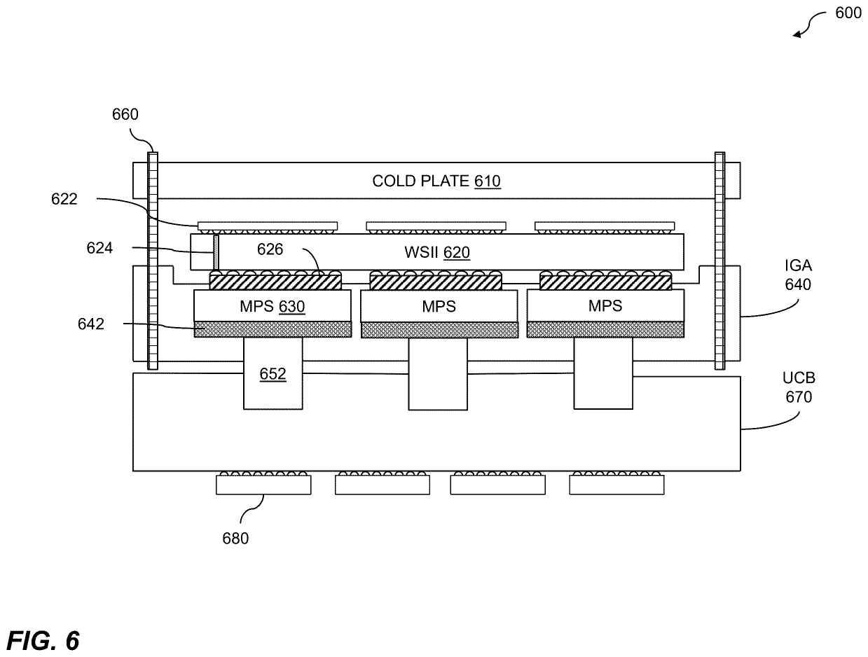

FIG. 6 is a cross section of an apparatus for back side power delivery for wafer-scale integration with an isometric grid compression plate. A wafer-scale silicon interposer (WSSI) is accessed. A front side of the WSSI is bonded to a plurality of functional chips. The WSSI includes a plurality of through-silicon vias (TSVs). The WSSI is associated with a first coefficient of thermal expansion (CTE). An anisotropic conductive film (ACF) is coupled to a back side of the WSSI. A plurality of modular power substrates (MPSs) is further coupled, based on the plurality of TSVs, to one or more functional chips. The MPSs are connected mechanically to a unified control board (UCB). The UCB includes a plurality of DC-to-DC power converters. The UCB is associated with a second coefficient of thermal expansion. The UCB sends DC power to the plurality of functional chips. The sending includes one or more voltage conversions and is based on the plurality of MPSs.

Power such as DC power can be sent by a universal control board (UCB) to a plurality of functional chips. The sending can be accomplished using a plurality of DC-to-DC converters, a plurality of modular power substrates (MPSs), and a plurality of through-silicon vias (TSVs). The plurality of functional chips can be bonded to a front side of a wafer-scale integration interposer (WSII). The plurality of MPSs can be attached to a backside of the WSII based on a plurality of conductive connecting materials. The conductive connecting materials can provide adhesion between the MPSs and the WSII. The conductive connecting materials can further provide configurable or preconfigured conduction paths between the MPSs and the WSII. The MPSs can be mechanically connected to the UCB based on a plurality of high-power sockets. The UCB can further include a plurality of DC-to-DC power converters. The attaching further includes compressing by an isometric grid array (IGA). The IGA compresses each conductive connecting material within the plurality of conductive connecting materials. The IGA can include a compression plate. The IGA can be stiffened based on a plurality of reinforcements. The stiffening can accomplish one or more goals associated with the apparatus. The stiffening can enable planar compression of the elastomer sheet. In embodiments, the planar compression is based on the one or more spring-loaded fasteners. The planar compression can be based on one or more clamps. The planar compression can enable consistent adhesion of the MPSs to a back side of the WSII. The planar compression can further enable reliable coupling of conduction paths through the conductive connecting material to contacts, pads, etc. associated with the MPSs and the WSII.

The through-silicon vias (TSVs) can be used to provide connections between a front side of the WSII and a back side of the WSII. The WSII can be used to achieve wafer-scale integration (WSI). The WSII can be used to mount various elements such as electrical elements and to provide interconnections among the mounted elements. The interposer can include other inorganic materials such as glass. An apparatus for power delivery is disclosed comprising: a wafer-scale integration interposer (WSII), wherein a front side of the WSII is bonded to a plurality of functional chips, wherein the WSII includes a plurality of through-silicon vias (TSVs); a plurality of modular power substrates (MPSs), wherein the plurality of MPSs is attached to a back side of the WSII by a plurality of conductive connecting materials; an isometric grid array (IGA), wherein the IGA includes a plurality of reinforcement structures, wherein each reinforcement structure in the plurality of reinforcement structures enables planar compression of each conductive connecting material within the plurality of conductive connecting materials; a cold plate, wherein the cold plate is attached to one or more functional chips, and wherein the cold plate is mounted to the IGA; and a unified circuit board (UCB), wherein the UCB is mechanically connected to the plurality of MPSs, wherein the UCB includes a plurality of DC-to-DC converters, wherein the UCB sends DC power to the plurality of functional chips bonded to the WSII.

The apparatus 600 includes a cold plate 610, wherein the cold plate is attached to one or more functional chips, and wherein the cold plate is mounted to an isometric grid array (IGA) (described below). The cold plate can be used to extract a portion of heat generated by functional chips as the functional chips operate. Recall that prodigious amounts of heat can be generated by chips and other electronic elements as they are operating. This point can be particularly relevant to high-performance chips. The mounting of the cold plate to a grid such as an IGA can be accomplished using clips, screws, bolts, clamps, and so on.

The apparatus 600 includes a wafer-scale integration interposer (WSII) 620, wherein a front side of the WSII is bonded to a plurality of functional chips, wherein the WSII includes a plurality of through-silicon vias (TSVs). The WSII can include inorganic materials or organic materials. In a usage example, the interposer can include a silicon interposer or a glass interposer. Micro-bumps discussed above can be used to mount the one or more functional chips to the front side of the WSII. Communications between the functional chips can be accomplished within metal layers of the interposer, thereby reducing latency and parasitics such as resistance, capacitance, and inductance, enabling improvement of signal integrity and/or bandwidth, etc. The reductions and improvements result from the opportunity for many more wires being established within the WSII compared to what would have been possible with a typical packaging interface. Thus, the WSII can enable extremely high bandwidth buses and control signals between chips mounted to the WSII. The WSII can include one or more optical waveguides. The optical waveguides can enable chip-to-chip communications via one or more wavelengths of light. The optical waveguides can comprise the buses and control signals between chips. The wafer interposer can also be used to attach additional boards, modules, components, and so on. The further attachments can be located on the opposite side of the wafer interposer from the mounted functional chips.

The apparatus 600 includes a plurality of functional chips, such as functional chip 622. The functional chips can include a processor chip, a multi-core processor chip, a graphics processor chip, a system-on-a-chip, a memory chip, an application-specific integrated circuit (ASIC), an artificial intelligence (AI) or machine learning (ML) accelerator, a vertical-cavity surface-emitting laser (VCSEL), and so on. The functional chips can include an integrated circuit designed for a flip-chip application. A chip design for a flip-chip application can include a chip for which connections to the chip are accomplished at the top layer of the chip. The connections can include positive and negative DC power connections, data connections, control connections, and so on. The various chip connections can include pads on the top layer of the chips. The functional chips can include a chip that can accomplish a processing function such as a deep learning function.

Various techniques can be used to make connections to the top of a functional chip. In a usage example, a technique based on micro-bumps can be used. A micro-bump can be associated with each connection point or pad on each chip. The micro-bumps can comprise a dense array of connection points or pads. The micro-bumps can include a material appropriate for mounting the chip to a substrate, a board, an interposer, and so on. The micro-bumps can include solder micro-bumps. These micro-bumps can be arranged in a ball grid array (BGA) or some other geometry. The WSII includes a plurality of through-silicon vias (TSVs) such as show at 624. The TSVs can provide a connection between the micro-bumps on the top side of the WSII and the connectors on the bottom side of the WSII. The TSV connections can be used to deliver power to the functional chips through the back side of the WSII.

The apparatus 600 includes a plurality of modular power substrates (MPSs) 630, wherein the plurality of MPSs is attached to a back side of the WSII by a plurality of conductive connecting materials. The apparatus can include a number of different conductive connecting materials. In embodiments, the plurality of conductive connecting materials comprises a plurality of elastomer sheets. In embodiments, the plurality of conductive connecting materials comprises a plurality of anisotropic conductive films (ACFs). In embodiments, the plurality of conductive connecting materials comprises a plurality of isotropic conductive adhesives (ICAs). An MPS can be coupled to one or more elements associated with the WSII. In embodiments, each MPS in the plurality of MPSs is coupled to one or more functional chips within the plurality of functional chips. In embodiments, each MPS within the plurality of MPSs is based on a form factor mirroring one or more corresponding functional chips within the plurality of functional chips on the front side of the WSII. The form factor of the MPS can be associated with or dependent on components mounted to the wafer interposer. In a usage example, the plurality of MPSs can be based on a form factor mirroring the corresponding functional chip. The form factor of the MPS can have a 1:1 relationship to the one or more corresponding functional chips or can include other shape factors. The MPSs can be based on a variety of materials. In a usage example, one or more MPSs within the plurality of MPSs comprise an inorganic substrate. An inorganic substrate can include a silicon substrate, a glass substrate, and so on. In another usage example, one or more MPSs within the plurality of MPSs comprise an organic substrate. The organic substrates can include substrates such as printed circuit boards. Recall that the functional chips are mounted to the front or top side of the WSII. In embodiments, the plurality of MPSs is attached to a back side of the WSII. Connections between the wafer interposer and the MPS can be accomplished using the conductive connecting materials 626. The plurality of conductive connecting materials attaches, which can include adhering, the MPSs to the WSII. The plurality of conductive connecting materials further provides conduction paths between pads or contacts associated with the MPSs and corresponding pads or contacts associated with the WSII.

An MPS 630 can include a plurality of step-down power modules and/or DC-to-DC converters. The DC-to-DC converters on an MPS can be placed across the MPS. The DC-to-DC converters on the MPSs can accomplish altering of a DC voltage. The altering the DC voltage can result in a second DC voltage. In a usage example, the power can be altered, wherein altering, by the plurality of MPSs, is accomplished by the DC power that was sent, and wherein the altering is based on a second voltage conversion. The second voltage conversion can include a second DC-to-DC voltage conversion. In embodiments, the second voltage conversion results in a voltage less than a threshold. The threshold can include a voltage appropriate to a voltage required by a functional chip. In embodiments, the threshold can include 1 volt.

The apparatus 600 includes an isometric grid array (IGA) 640, wherein the IGA includes a plurality of reinforcement structures 642, wherein each reinforcement structure in the plurality of reinforcement structures enables planar compression of each conductive connecting material within the plurality of conductive connecting materials. Each reinforcement structure 642 in the plurality of reinforcement structures can stiffen each MPS in the plurality of MPSs, respectively. In embodiments, the planar compression is based on the one or more spring-loaded fasteners. The planar compression can be based on one or more clamps. The clamps can provide more compression force than the spring-loaded fasteners. Both spring-loaded fasteners and clamps can be used. The MPS can be stiffened for a variety of purposes. Recall that MPSs are attached to the back side of the WSII based on a plurality of conductive connecting materials. When the conductive connecting materials comprise certain materials, such as elastomer sheets, a sufficient force can be applied substantially equally across the plurality of MPSs to form a reliable electrical coupling between the MPSs and the WSII. When an adhesive material is used, The IGA can be used to apply sufficient force to enable adhesion. In embodiments, the IGA comprises a compression plate. In other embodiments, the IGA maintains a coplanarity of the WSII. Recall that a cold plate is mounted to the IGA. In embodiments, the mounting is based on one or more spring-loaded fasteners 660. Any other fasteners, such as a screw, clamp, and so on, can be used. The spring-loaded fasteners can squeeze the WSSI between the cold plate and the IGA. The pressure on the WSSI can be exerted by the IGA through the MPSs after they have been inserted into the reinforcement structure. This can enable planar compression on the WSSI. In embodiments, the planar compression is based on the one or more spring-loaded fasteners.

The coplanarity of each MPS can enable adhesion and/or connection by the conductive connecting materials without causing the WSII to deflect, crack, fracture, and so on. Each reinforcement structure can be formed using a variety of techniques. Usage examples can include depositing, on each MPS within the plurality of MPSs, the reinforcement structure. The reinforcement structure can be deposited using a fabrication technique such as chemical vapor deposition (CVD). Other embodiments include gluing, to each MPS within the plurality of MPSs, the reinforcement structure. The gluing can be accomplished using adhesives such as an epoxy, cyanoacrylate, and so on.

The apparatus 600 includes a unified circuit board (UCB) 670, wherein the UCB is mechanically connected to the plurality of MPSs, wherein the UCB includes a plurality of DC-to-DC converters, wherein the UCB sends DC power to the plurality of functional chips bonded to the WSII. The sending can be based on the plurality of MPSs and the plurality of TSVs. The MPS discussed previously can be mechanically connected to a unified control board (UCB). An MPS can include a connector, where the connector can be used to mechanically connect the MPS to the UCB. For the apparatus 600, the connector can comprise a socket 652 on the UCB. The socket can comprise a high-power socket, a high voltage socket, and so on. The mechanical connection can include one or more plugs, pins, terminals, contacts, etc. from the UCB which can be inserted into the socket. In a usage example, the mechanical connection can be based on a high voltage socket, wherein the high voltage socket transfers power from the UCB to the plurality of MPSs. The high voltage socket can be used to provide a first DC voltage that can be converted to a second DC voltage by one or more DC-to-DC converters. The mechanical connection can accommodate a maximum lateral displacement of the UCB due to thermal expansion during operation. In a usage example, the mechanical connection can include a compliant connector. The lateral displacement can result from thermal expansion of the WSII, the UCB, and/or the MPS during operation.

The UCB includes a plurality of DC-to-DC power converters 680. As described above, each DC-to-DC power converter in the plurality of DC-to-DC power converters can include a mechanical connection to a respective MPS in the plurality of MPSs. The mechanical connection between each DC-to-DC converter and a respective MPS can enable power transfer, control, and so on. The mechanical connections between the plurality of DC-to-DC converters and the plurality of MPSs can remain reliable when the DC-to-DC converters and the MPSs are operating. The mechanical connection can accommodate a maximum lateral displacement of the UCB due to thermal expansion during operation. The handling a maximum lateral displacement is critical to maintaining reliable mechanical connections between and among components, the WSII, one or more UCBs, one or more MPSs, and so on.

The UCB 670 can include a digital controller chip (not shown). The DC-to-DC converters can be controlled by a control chip associated with the UCB. The digital controller chip can control power delivery to the plurality of functional chips. The controlling power delivery can include enabling or disabling power transfer, controlling an input voltage to and an output voltage from a DC-to-DC converter, and the like. A usage example can include matching each DC-to-DC power converter within the plurality of DC-to-DC power converters included on the UCB to one or more respective MPSs in the plurality of MPSs. DC power from a DC-to-DC converter can be sent to an MPS via an interconnect on the UCB. DC power can be fed to the DC-to-DC converters. Recall that an MPS can include a connector that can accommodate lateral displacement of the UCB due to thermal expansion during operation. The connector can accomplish other functions. In a usage example, the connector can include one or more power control signals from the digital controller chip to the plurality of MPSs. The control signals can enable and disable elements such as controller chips and DC-to-DC converters, can provide instructions to controller chips, etc. In a further usage example, the connector can carry at least a portion of DC power from the plurality of MPSs to the plurality of functional chips. As explained above and throughout, the WSII and the UCB can expand at different rates due to different CTEs. Thus, the MPSs that are attached to the UCB can also move, which can cause connections associated with the elastomer sheets between the WSII and the MPSs to become unreliable. To mitigate this movement due to expansion, as explained previously, the MPS can be designed modularly, effectively isolating movement between MPSs. In addition, the socket, which can be a high-power socket, a high voltage socket, etc., can comprise a compliant connector.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions generally referred to herein as a “circuit,” “module,” or “system” may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for power delivery comprising:
accessing a wafer-scale silicon interposer (WSSI), wherein a front side of the WSSI is bonded to a plurality of functional chips, wherein the WSSI includes a plurality of through-silicon vias (TSVs), and wherein the WSSI is associated with a first coefficient of thermal expansion (CTE);
coupling, by an anisotropic conductive film (ACF), to a back side of the WSSI, a plurality of modular power substrates (MPSs), wherein each MPS is further coupled, based on the plurality of TSVs, to one or more functional chips within the plurality of functional chips;
connecting mechanically the plurality of MPSs, to a unified control board (UCB), wherein the UCB includes a plurality of DC-to-DC power converters, and wherein the UCB is associated with a second coefficient of thermal expansion; and
sending DC power, by the UCB, to the plurality of functional chips, wherein the sending includes one or more voltage conversions, wherein the sending is based on the plurality of MPSs.

2. The method of claim 1 wherein the first coefficient of thermal expansion is different than the second coefficient of thermal expansion.

3. The method of claim 2 wherein the connecting mechanically is based on a plurality of high voltage sockets.

4. The method of claim 3 wherein the connecting mechanically accommodates a lateral displacement between the WSSI and the UCB due to thermal expansion during operation.

5. The method of claim 1 wherein the coupling enables an electrical connection without a solder reflow process.

6. The method of claim 1 wherein the ACF comprises a plurality of conductive particles.

7. The method of claim 6 wherein the plurality of conductive particles forms a plurality of conductive paths within the ACF.

8. The method of claim 7 wherein the plurality of conductive paths within the ACF is oriented in a single direction.

9. The method of claim 7 wherein the plurality of conductive paths is based on thermocompression.

10. The method of claim 7 wherein the plurality of conductive paths is based on an electric field.

11. The method of claim 7 wherein the plurality of conductive paths is based on a magnetic field.

12. The method of claim 1 wherein a first voltage conversion is accomplished by the plurality of DC-to-DC power converters included on the UCB.

13. The method of claim 12 wherein the sending includes a second voltage conversion.

14. The method of claim 13 wherein the second voltage conversion is accomplished by the plurality of MPSs.

15. The method of claim 1 wherein the plurality of MPSs is based on a form factor mirroring one or more corresponding functional chips within the plurality of functional chips.

16. The method of claim 15 wherein the form factor mirroring is based on the front side of the WSSI.

17. The method of claim 1 wherein each MPS in the plurality of MPSs includes one or more rigid-flex strips.

18. The method of claim 17 wherein the one or more rigid-flex strips enable power control of each corresponding MPS by a digital controller chip coupled to the UCB.

19. An apparatus for power delivery comprising:
a wafer-scale silicon interposer (WSSI), wherein a front side of the WSSI is bonded to a plurality of functional chips, wherein the WSSI includes a plurality of through-silicon vias (TSVs), and wherein the WSSI is associated with a first coefficient of thermal expansion;
a plurality of modular power substrates (MPSs), wherein the plurality of MPSs is coupled to a back side of the WSSI, wherein each MPS is further coupled, based on the plurality of TSVs, to one or more functional chips within the plurality of functional chips;
a unified control board (UCB), wherein the UCB is connected mechanically to the plurality of MPSs, wherein the UCB includes a plurality of DC-to-DC power converters, and wherein the UCB is associated with a second coefficient of thermal expansion; and
an anisotropic conductive film (ACF), wherein the ACF couples the plurality of MPSs to a back side of the WSSI, and wherein the ACF accommodates a lateral displacement between the WSSI and the UCB due to thermal expansion during operation.

20. A system for power delivery comprising:
a wafer-scale silicon interposer (WSSI), wherein a front side of the WSSI is bonded to a plurality of functional chips, wherein the WSSI includes a plurality of through-silicon vias (TSVs), and wherein the WSSI is associated with a first coefficient of thermal expansion;
a plurality of modular power substrates (MPSs), wherein the plurality of MPSs is coupled to a back side of the WSSI, wherein each MPS is further coupled, based on the plurality of TSVs, to one or more functional chips within the plurality of functional chips;
a unified control board (UCB), wherein the UCB is connected mechanically to the plurality of MPSs, wherein the UCB includes a plurality of DC-to-DC power converters, and wherein the UCB is associated with a second coefficient of thermal expansion; and
an anisotropic conductive film (ACF), wherein the ACF couples the plurality of MPSs to a back side of the WSSI, and wherein the ACF accommodates a lateral displacement between the WSSI and the UCB due to thermal expansion during operation, wherein the system, when provided DC power, is configured to:
send DC power, by the UCB, to the plurality of functional chips, wherein the sending includes one or more voltage conversions, wherein the sending is based on the plurality of MPSs.
